(19) United States
(12) Patent Application Publication
(10) Pub. No.: US 2010/0169735 A1
(43) Pub. Date: Jul. 1, 2010

(54) LOW DENSITY PARITY CHECK CODE ROW UPDATE INSTRUCTION

(75) Inventors: Eric BISCONDI, Opio (FR); David J. HOYLE, Austin, TX (US); Tod D. WOLF, Richardson, TX (US)

Correspondence Address: TEXAS INSTRUMENTS INCORPORATED, P O BOX 655474, M/S 3999, DALLAS, TX, 75265, US

(73) Assignee: TEXAS INSTRUMENTS INCORPORATED, Dallas, TX (US)

(21) Appl. No.: 12/347,731

(22) Filed: Dec. 31, 2008

(51) Int. Cl. H03M 13/05; G06F 11/07

(52) U.S. Cl. 714/752; 714/E11.021

(57) ABSTRACT

Apparatus for optimizing low-density parity check (“LDPC”) decoding in a processor is disclosed herein. A processor in accordance with the present disclosure includes an LDPC decoder row update execution unit. The LDPC decoder row update execution unit accelerates an LDPC row update computation by performing a logarithm estimation and a magnitude minimization in parallel. The execution unit is activated by execution of an LDPC row update instruction. The execution unit adds a minimum of magnitudes of two input values to a difference of estimated logarithms of exponential functions of a sum and a difference of the two input values to produce a row update value.

### BACKGROUND

Error correcting codes are used to automatically detect and correct errors in a received data signal. Generally, a data signal transmitter applies a selected encoding algorithm to a transmitted data signal. A receiver applies an appropriate decoder to determine whether the received signal was corrupted while propagating through the transmission channel and to correct any errors detected. Low density parity check (“LDPC”) codes are one of a variety of error correcting codes. LDPC codes were originally identified in the early 1960s, but were largely forgotten until the late 1990s. LDPC codes have been selected to provide error correction for digital video broadcasting satellite (“DVB-S2”) systems, 3GPP Long Term Evolution (“LTE”) wireless systems, and IEEE 802.16e (“WIMAX”) systems.

The theoretical upper limit of a communication channel's capacity, the Shannon limit, can be expressed in terms of bits per symbol at a certain signal-to-noise ratio. One goal of code design is to achieve rates approaching the Shannon limit. LDPC codes operate at near the Shannon limit. LDPC codes offer performance that is equivalent to or better than turbo codes for large code words. Moreover, the computational processing required by an LDPC decoder is simpler and better suited to parallelization than the processing required by turbo codes.

LDPC codes can be represented by bipartite graphs, often called Tanner graphs. In a Tanner graph, one set of nodes, called variable nodes, represents the bits of a codeword, and the other set of nodes, called check nodes, represents the parity check constraints that define the code. The graph's edges connect check nodes to variable nodes. LDPC decoders exchange messages along the edges of the graph, and update the messages by performing computations in the nodes. Messages are exchanged, i.e., the decoding process iterates, until a codeword is detected, or a maximum number of iterations is performed. One such message passing algorithm is known as belief propagation.

In an LDPC decoder applying belief propagation, the messages transmitted along the edges of the graph represent probabilities. The belief propagation algorithm takes as input at each of the variable nodes, data received from the communication channel representing probabilities. During an iteration of the algorithm, bit probability messages are passed from the variable nodes to the check nodes, updated, and sent back and summed at the variable nodes. Many iterations may be required to resolve a codeword. Means of improving LDPC decoder efficiency are desirable.

### SUMMARY

Accordingly, various techniques are herein disclosed for improving low density parity check (“LDPC”) decoder efficiency. In accordance with at least some embodiments, a processor includes an LDPC decoder row update execution unit. The LDPC decoder row update execution unit accelerates an LDPC row update computation by performing a logarithm estimation and a magnitude minimization in parallel.

In other embodiments, a system includes a receiver. The receiver includes a processor based LDPC decoder. The processor executes an LDPC row update instruction that causes the processor to compute, at least a portion of, a check node update value.

In yet other embodiments, an LDPC decoder includes a processor. The processor includes an LDPC check node update execution unit that computes, at least a portion of, a check node update value.

### BRIEF DESCRIPTION OF THE DRAWINGS

In the following detailed description, reference will be made to the accompanying drawings, in which:

FIG. 1 shows an exemplary block diagram of an execution unit that implements the MINSTAR instruction with signed inputs in accordance with various embodiments;

FIG. 2 shows an exemplary block diagram of an execution unit that implements the MINSTAR instruction with unsigned inputs in accordance with various embodiments;

FIG. 3 shows various illustrative graphical representations of a log function implemented in a MAXSTAR block in accordance with various embodiments;

FIG. 4 shows an illustrative representation of a MINSTAR instruction in accordance with various embodiments;

FIG. 5 shows an illustrative representation of a MINSTAR SIMD instruction execution in accordance with various embodiments;

FIG. 6 shows a block diagram of a processor including a MINSTAR execution unit for LDPC decoding in accordance with various embodiments;

FIG. 7 shows a system that uses LDPC decoding in accordance with various embodiments; and

FIG. 8 shows a flow diagram for a method for computing an LDPC row update value in an LDPC row update execution unit in accordance with various embodiments.

### NOTATION AND NOMENCLATURE

Certain terms are used throughout the following description and claims to refer to particular system components. As one skilled in the art will appreciate, companies may refer to a component by different names. This document does not intend to distinguish between components that differ in name but not function. In the following discussion and in the claims, the terms “including” and “comprising” and “e.g.” are used in an open-ended fashion, and thus should be interpreted to mean “including, but not limited to . . . ”. The term “couple” or “couples” is intended to mean either an indirect or direct wired or wireless connection. Thus, if a first component couples to a second component, that connection may be through a direct connection, or through an indirect connection via other components and connections. The term “system” refers to a collection of two or more hardware and/or software components, and may be used to refer to an electronic device or devices, or a sub-system thereof. Further, the term “software” includes any executable code capable of running on a processor, regardless of the media used to store the software. Thus, code stored in non-volatile memory, and sometimes referred to as “embedded firmware,” is included within the definition of software.

### DETAILED DESCRIPTION

The following discussion is directed to various embodiments of the invention. Although one or more of these embodiments may be preferred, the embodiments disclosed should not be interpreted, or otherwise used, as limiting the scope of the disclosure, including the claims. In addition, one skilled in the art will understand that the following description has broad application, and the discussion of any embodiment is meant only to be exemplary of that embodiment, and not intended to intimate that the scope of the disclosure, including the claims, is limited to that embodiment.

Disclosed herein are various systems and methods for improving the performance of a low-density parity check (“LDPC”) code decoder. LDPC decoders can be implemented in software, hardware, or a combination of hardware and software. A digital signal processor (“DSP”) can be used to implement an LDPC decoder. Unfortunately, each iteration of the decoding algorithm can require execution of a numerous instructions. Embodiments of the present disclosure reduce the number of instructions executed during each decoding iteration by including instructions that accelerate check node processing. Furthermore, the parallel nature of the check node updates allows for addition efficiency increases by processing multiple check nodes in parallel.

An LDPC code can be represented as a matrix H. Each column of the parity check matrix H represents a variable node, and each row represents a check node. The number of rows (i.e., check nodes) in H is represented as m, and the number of columns (i.e., variable nodes) is represented as j. A codeword includes j symbols.

An embodiment of an LDPC decoder is initialized as follows:

$$L ( {q}_{j} ) = \frac{2 {r}_{j}}{{σ}^{2}} , \qquad ( 1 )$$

where rⱼ is a received symbol, and σ² denotes an estimate of channel error variance, initializes a variable node, L(qⱼ), into the log probability domain (i.e., a log-likelihood ratio). The check node update results, Rₘⱼ, are initialized to zero,

Rₘⱼ=0. (2)

The following equations describe a row update:

L(qₘⱼ)=L(qⱼ)−Rₘⱼ, (3)

describes a per row probability derivation for each column j of each row m of the checksum.

$${A}_{mj} = {\sum }_{{n ∈ N ( m )}_{n \neq j}} Ψ ( L ( {q}_{mn} ) ) , \qquad ( 4 )$$

derives an amplitude variable/check node, where N(m) is defined as the set of all columns in a given row m for which codeword bits contribute to the checksum. The function Ψ is defined in equation (7) below.

$${s}_{mj} = {\prod }_{{n ∈ N ( m )}_{n \neq j}} sgn ( L ( {q}_{mn} ) ) , \qquad ( 5 )$$

derives a sign for each variable/check node as an odd/even determination of the number of negative probabilities, excluding each row's own contribution.

Rₘⱼ=−sₘⱼΨ(Aₘⱼ) (6)

computes an updated row value estimate.

$$Ψ ( x ) ≡ log ( \vert tanh ( \frac{x}{2} ) \vert ) \qquad ( 7 )$$

is its own negative inverse, i.e., Ψ(Ψ(x))=−|x|.

The column update, wherein the probability estimates for each variable node are updated, is described by:

$$L ( {q}_{j} ) = {\sum }_{m ∈ M ( j )} {R}_{mj} - \frac{2 {r}_{j}}{{σ}^{2}} , \qquad ( 8 )$$

where M(j) is the set of all rows for a given column j of checksum equations to which input bit j contributes to the checksum.

Equations (4) and (7) can be replaced with the following:

Aₘⱼ(x,y)=sgn(x)sgn(y)min(|x|, |y|)+log (1+e^{-|x+y|})−log (1+e^{-|x-y|}), (9)

where x and y constitute a pair of different variable node outputs L(qₘₙ), and as in equation (4), n ∈ N(m) and n≠j. The sgn(x) function outputs 0 if x≧0, and 1 if x<0.

Equation (9) can be decomposed into two smaller equations:

Aₘⱼ(x,y)=sgn(x)sgn(y)f(x,y), and (10)

f(x,y)=min(|x|, |y|)+log(1+e^{-|x+y|})−log(1+e^{-|-y|}). (11)

Equation (11) can be implemented on a DSP as part of a software LDPC decoder. Table 1 below illustrates the number of DSP instructions that may be required to implement equation (11).

TABLE 1

| Function | Times Executed | Instruction | Totals |
|---|---|---|---|
| Absolute Value | 4 | ABS | 4 |
| Min(x, y) | 1 | CMP & MOV(2) | 3 |
| Addition | 4 | ADD | 4 |
| Subtraction | 2 | SUB | 2 |
| Exponentiation | 2 | LD | 2 |
| Natural Logarithm | 2 | LD | 2 |
| Total Instructions | | | 17 |

Table 1 assumes that the Exponentiation and Natural Logarithm functions are evaluated by table look-up.

Table 2 list the possible code rates of IEEE 802.16e with the maximum number of edges (RowMax) that are processed per row update. The rightmost column shows the number of times that equation (11) may be executed per iteration. Thus, if convergence requires 50 iterations, then 124 million instructions will be executed (17 instructions*50 iterations*145,920 times) to perform a rate 5/6 row update.

TABLE 2

| Code | | | |
|---|---|---|---|
| Rate | RowMax | Number of Rows | RowMax * (RowMax − 1) * m |
| ½ | 7 | 1152 | 48,384 |
| ⅔ | 11 | 768 | 84,480 |
| ¾ | 15 | 576 | 120,960 |
| ⅚ | 20 | 384 | 145,920 |

Embodiments of the present disclosure improve LDPC decoder performance by replacing the instructions of Table 1 with a single instruction. In at least some embodiments, the new instruction is termed MINSTAR, and performs the functions of equation (11).

MINSTAR(x,y)=min(|x|,|y|)+log(1+e^{-|x+y|})−log(1+e^{-|x-y|}) (12)

Thus, equation (9) may be rewritten as:

Aₘⱼ(x,y)=sgn(x)sgn(y)MINSTAR(x,y) (13)

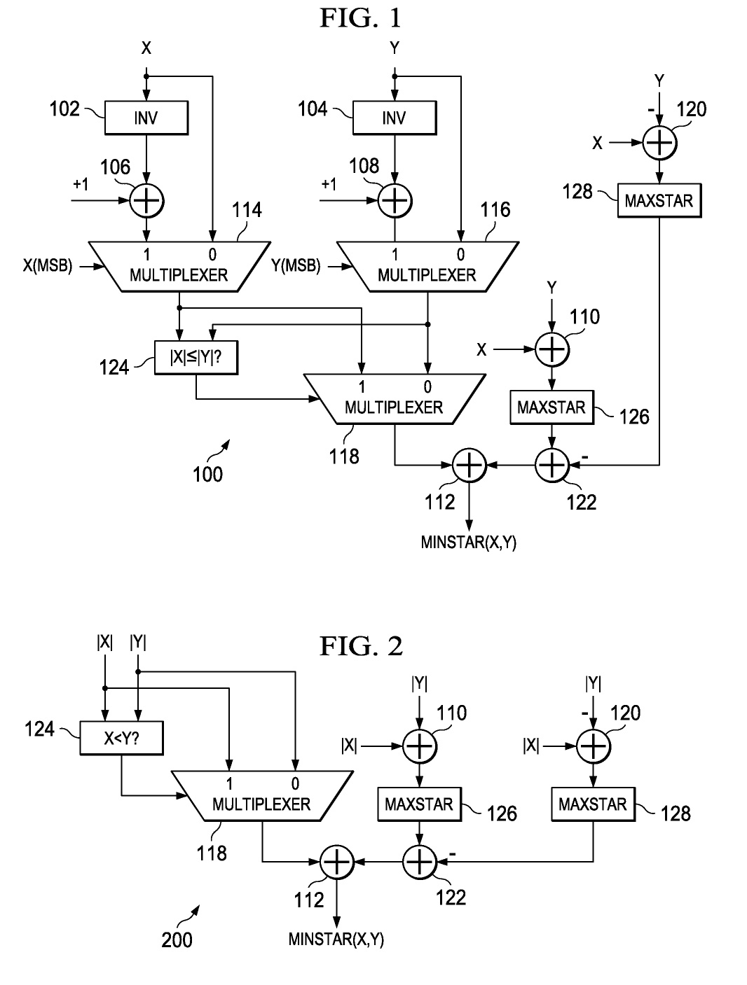

FIG. 1 shows an exemplary block diagram of an execution unit 100 that implements the MINSTAR instruction with signed inputs in accordance with various embodiments. The MINSTAR execution unit 100 allows a processor so equipped to execute equation (9) with one instruction rather than multiple instructions. The MINSTAR execution unit comprises inverters 102, 104, adders 106, 108, 110, 112, multiplexers 114, 116, 118, subtractors 120, 122, comparator 124, and MAXSTAR blocks 126, 128. Inverter 102 and adder 106, and inverter 104 and adder 108 form 2's complementers to negate x and y. The most significant bit of x and y control multiplexers 114 and 116 respectively to cause the multiplexers 114, 116 to output the absolute value of x and y. The multiplexer 118 produces the minimum of x and y absolute values. The output of comparator 124 controls multiplexer 118.

The MAXSTAR blocks 126, 128 implement the function:

f(z)=log(1+e^{-|z|}), (14)

where z is x+y for input to MAXSTAR 126, and x−y for input to MAXSTAR 128.

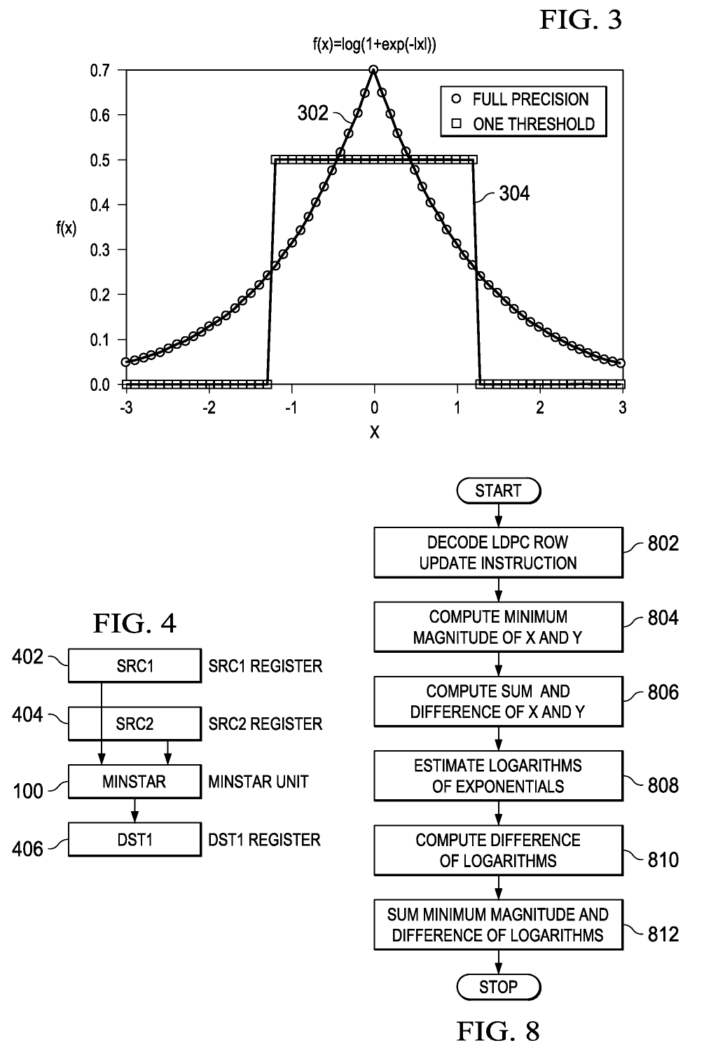

f(z) can be implemented in a variety of ways. In some embodiments, a high precision version of f(z) is stored in a look-up table. A curve 302 illustrating the high precision version is shown in FIG. 3. Some embodiments implement a lower precision version of f(z) as a look-up table or via software. For example, a 1 bit precision version of f(z) is shown in curve 304. Curve 304 is defined by two input parameters. The first parameter defines a threshold and the second parameter defines a data value. The curve 304 has a threshold of approximately 1.2 and a data value of 0.5. Some embodiments may implement multiple programmable thresholds and multiple programmable data values to produce higher resolution curves. Some embodiments may include only portion of the f(z) curve, for example, x>0.

FIG. 2 shows an exemplary block diagram of an execution unit 200 that implements the MINSTAR instruction with unsigned inputs in accordance with various embodiments. This embodiment can be used when the absolute values of x and y have been previously calculated, resulting in a 15× reduction in instruction count. MINSTAR execution unit 200 includes a subset of the functional blocks of execution unit 100. Preferably, no functional blocks associated with determining an absolute value are included. Because the inputs to the execution unit 200 are unsigned, the results of the MINSTAR(x,y) of execution unit 200 will differ from those of the signed execution unit 100. If x and y are like-signed then execution units 100 and 200 produce the same output. If x and y are differently signed then execution units 100 and 200 produce different outputs. As a result, if x and y are close in magnitude, but have opposite signs, the output will be −2×dataValue of the MAXSTAR block 126, 128.

As previously explained, the LDPC data is in the log probability domain. Magnitudes near zero represent low probabilities of a correct result, and magnitudes near infinity represent high probabilities of a correct result. The error introduced by the execution unit 200 lowers the value of the edge by 2×dataValue, and consequently lowers the correctness probability of that edge. Fortunately, this error has little effect on the overall performance of an LDPC decoder. The error has a more pronounced effect on the initial iterations (because the edges are closer in magnitude); but as the edges converge to a solution; the error becomes insignificant.

In some embodiments, a MINSTAR instruction takes the form:
MINSTAR src1, src2, dst
   and provides the functionality of execution unit 100 or 200 explained above, depending on whether the inputs are signed or unsigned. Src1 and src2 specify the x and y operand locations, and dst specifies a location for result storage. In some embodiments, src1, src2, and dst specify register locations.

FIG. 4 shows an illustrative representation of a MINSTAR instruction in accordance with various embodiments. In FIG. 4 source registers 402, 404 provide input parameters x and y to the MINSTAR execution unit 100 (or 200), and a destination register 406 receives the output MINSTAR(x,y). Thus, depending on whether signed or unsigned operands are used, the MINSTAR instruction provides either a 17× or a 15× reduction in instruction count.

Some embodiments further accelerate LDPC decode processing by including multiple MINSTAR execution units. Such embodiments allow multiple row update equations (11) to be processed in parallel. Embodiments can employ either the signed or unsigned execution units 100, 200 as needed.

Single instruction/multiple data processing (“SIMD”) is a parallel processing paradigm in which one instruction causes multiple execution units to perform the same processing on different data. Embodiments employ SIMD techniques to parallelize MINSTAR processing. An embodiment with a datapath of width A bits, and data element precision of B bits may run A/B functions in parallel when sufficient execution units are provided.

Embodiments employing SIMD MINSTAR processing can improve LDPC decoder efficiency by a factor corresponding to the number of MINSTAR execution units operating in parallel. An embodiment comprising 8 parallel MINSTAR execution units can increase LDPC decoder efficiency from 15× to 17× to 120× to 136×, reducing the number of instructions executed from 124 million to either 1.03 million (signed) or 912,000 (unsigned).

An embodiment with a 128 bit datapath, employing 16-bit data, and having 8 execution units can, for example, implement the instruction
MINSTAR1_{—}8H src1, src2, dst
   to perform 8 MINSTAR functions in parallel. Src1 and src2 respectively specify the locations of 128-bit values comprising eight 16-bit wide x and y operands. Dst specifies the storage location for the eight 16-bit MINSTAR result values packed into a 128-bit value.

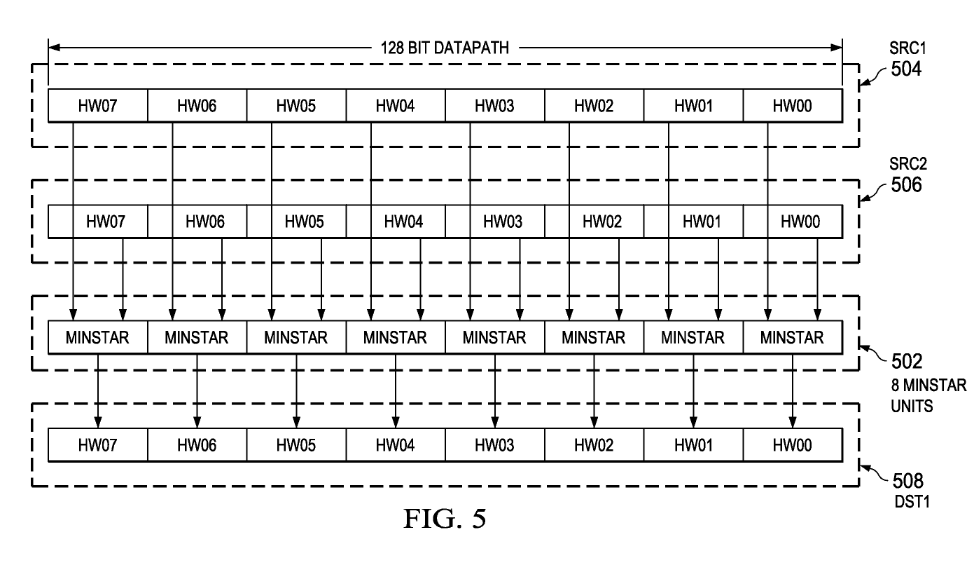

FIG. 5 shows an illustrative representation of a MINSTAR1_{—}8H SIMD instruction execution in accordance with various embodiments. In the embodiment shown, the MINSTAR execution units 502, which may comprise, for example, execution units 100 or 200 are configured to process 16-bit data. 16-bit x and y values are delivered to the execution units 502 in parallel from SRC1 504 and SRC2 506 respectively via a 128-bit data path. The 8 16-bit values resulting from MINSTAR 502 processing are likewise transferred in parallel to DST1 over a 128-bit data path.

Embodiments of the present disclosure encompass various SIMD configurations applicable to different data path and parameter widths. For example, an embodiment having a 128-bit data path and configured to process 8-bit data values can implement 16 MINSTAR execution units 100, 200. Sixteen 8-bit x values and sixteen 8-bit y values are preferably packed into respective 128-bit values and fed to the MINSTAR execution units 100, 200. Sixteen 8-bit result values are produced by the MINSTAR execution units 100, 200 and stored in a 128-bit destination storage location. A 16 MINSTAR execution unit 100, 200 embodiment can decrease the number of instructions executed in LDPC decoding from 124 million to 516,800 (signed) or 456,000 (unsigned).

An embodiment having a 128-bit data path and configured to process 32-bit data values can implement 4 MINSTAR execution units 100, 200. Four 32-bit x values and four 32-bit y values are preferably packed into respective 128-bit values and fed to the MINSTAR execution units 100, 200. Four 32-bit result values are produced by the MINSTAR execution units 100, 200 and stored in a 128-bit storage location. A 4 MINSTAR execution unit 100, 200 embodiment can decrease the number of instructions executed in LDPC decoding from 124 million to approximately 2 million.

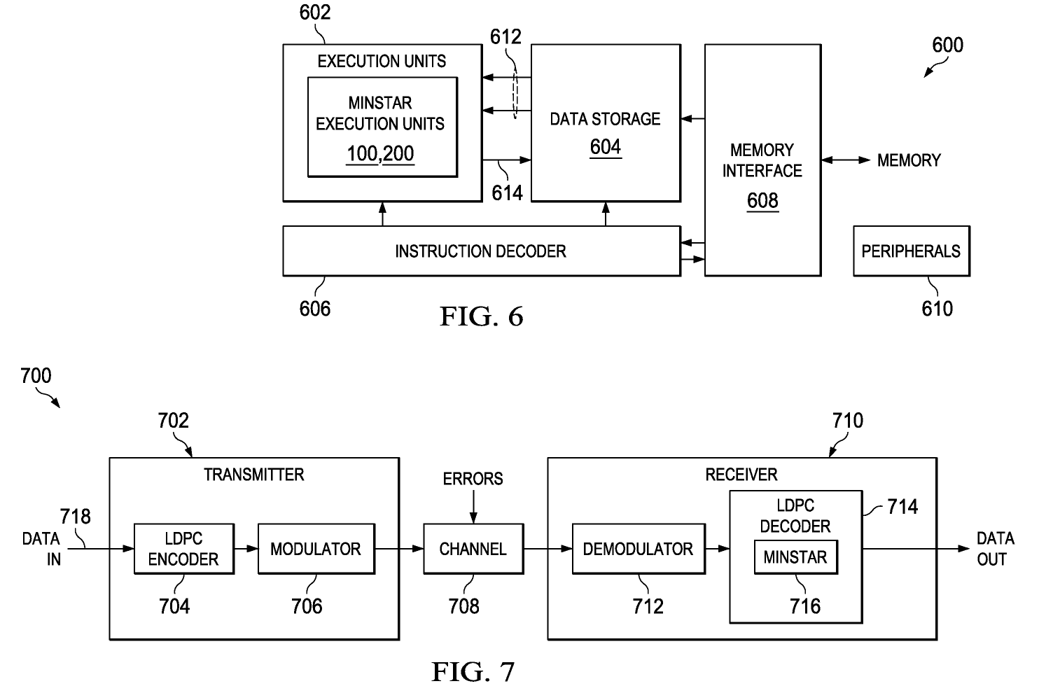

FIG. 6 shows a block diagram of a processor 600 comprising a MINSTAR execution unit 100, 200 for LDPC decoding in accordance with various embodiments. Processor 600 comprises execution units 602, data storage 604, instruction decoder 606, memory interface 608, and peripherals 610.

Execution units 602 can comprise various functional units that perform logical and/or arithmetic operations. Embodiments may perform, for example, floating point and/or fixed-point and/or integer arithmetic operations. Execution units 602 may comprise multiple similar or identical execution units to enable SIMD processing. As shown, execution units 602 comprise one or more MINSTAR execution units 100, 200 to accelerate LDPC row processing.

Parameters are provided to the MINSTAR execution unit 100, 200 from the data storage 604 via source busses 612, and MINSTAR results are returned to the data storage 604 via destination bus 614. In embodiments including multiple MINSTAR execution units 100, 200, the source and destination busses 612, 614 are configured to propagate multiple data values at once. Accordingly, in such embodiments, data storage 604 is configured to store multiple source/destination data values for delivery to, or receipt from, the MINSTAR execution units 100, 200. For example, the data storage 604 may store sets of eight 16-bit source operands in a 128-bit register for delivery to eight 16-bit MINSTAR execution units 100, 200, and store eight 16-bit MINSTAR result values in a 128-bit register. Embodiments may implement data storage 604 as hardware registers or memory.

Instruction decoder 606 includes logic to decode a MINSTAR instruction. As explained above, embodiments may include various versions of a MINSTAR instruction (e.g., SIMD or single instruction single data, signed or unsigned input, etc.). The instruction decoder 606 recognized the various MINSTAR opcodes implemented in a processor embodiment, and directs the data storage 604 and MINSTAR execution units 100, 200 to perform MINSTAR processing when a MINSTAR opcode is encountered in an instruction stream.

The memory interface 608 fetches instructions and/or data from memory external to the processor 600 and provides those instructions and/or data to the instruction decoder 606 and the data storage 606. Some embodiments may include cache memories interstitially disposed between the memory interface 608 and the instruction decoder 606 and data storage 604.

Peripherals 610 can comprise a wide variety of functional blocks to enhance processor performance. For example, DMA controllers, interrupt controllers, timers, and/or various input/output device are peripherals included in some embodiments.

FIG. 7 shows a system comprising an LDPC decoder incorporating MINSTAR processing in accordance with various embodiments. A transmitter 702 includes an LDPC encoder 704 and a modulator 706. The LDPC encoder 704 adds redundancy to the data 718 supplied for transmission by multiplying the data with a sparse matrix. The modulator 706, modulates the encoded data using, for example, orthogonal frequency division multiplexing. The encoded and modulated data is transmitted into a channel 708. Errors may be introduced into the transmitted data as the data propagates through the channel 708.

A receiver 710 includes a demodulator 712 and an LDPC decoder 714. The LDPC decoder 714 includes MINSTAR processing 716 to accelerate decoding. The receiver 710 detects the signals transmitted by the transmitter 702 with distortion added by propagation through the channel 708. The demodulator 712 demodulates the signals in accordance with the modulation performed by modulator 706 of the transmitter 702. The demodulated signals are supplied to the LDPC decoder 714 for forward error correction. By including MINSTAR processing, embodiments of the present disclosure can accelerate LDPC software decoding by a factor of 15 or more. Error corrected data is supplied to a user of the system.

FIG. 8 shows a flow diagram for a method for computing an LDPC row update value in an LDPC row update execution unit in accordance with various embodiments. Though depicted sequentially as a matter of convenience, at least some of the actions shown can be performed in a different order and/or performed in parallel. Additionally, some embodiments may perform only some of the actions shown. In block 802, a processor is executing an LDPC decoding program. As part of an LDPC row update computation, the processor 600 preferably fetches from instruction storage (e.g., volatile or non-volatile random access memory) an LDPC row update instruction. In some embodiments, the row update instruction is the MINSTAR instruction disclosed herein.

An instruction decoder 606 in the processor 600 decodes the row update instruction to provide control to the processor's row update execution units 100, 200 and data storage system 604. The data storage unit 604, which in come embodiments can comprise registers, random access memory, etc., provides operands to the execution units 100, 200 based on the decoded instruction.

In block 804, the execution units 100, 200 begin processing of the input operands (x and y). The minimum magnitude of the two operands is computed. The sum and difference of the two operands is computed in block 806. The computed sum and difference of x and y is provided as input to the MAXSTAR blocks 126, 128 of the execution units 100, 200, where the logarithms of exponentials raised to the sum and difference are estimated in block 808. The difference of the logarithmic outputs of the MAXSTAR blocks 126, 128 is computed in block 810.

In block 812, the minimum magnitude of x and y is summed with the difference of the two logarithms to produce an execution unit output (i.e., a row update value). Some embodiments compute row update values for a plurality of rows in parallel.

While illustrative embodiments of this present disclosure have been shown and described, modifications thereof can be made by one skilled in the art without departing from the spirit or teaching of this present disclosure. The embodiments described herein are illustrative and are not limiting. Many variations and modifications of the system and apparatus are possible and are within the scope of the present disclosure. For example, while various SIMD embodiments employing a 128-bit data path have been described, embodiments are not limited to any particular data path width. Similarly, embodiments are not limited to any particular data width or number of execution units. Accordingly, the scope of protection is not limited to the embodiments described herein, but is only limited by the claims which follow, the scope of which shall include all equivalents of the subject matter of the claims.

What is claimed is:

1. A processor, comprising:
a low density parity check (“LDPC”) decoder row update execution unit that accelerates an LDPC row update computation by performing a logarithm estimation and a magnitude minimization in parallel.

2. The processor of claim 1, wherein the execution unit is activated by execution of an LDPC row update instruction.

3. The processor of claim 1, wherein the execution unit comprises logic that determines an absolute value of an input value.

4. The processor of claim 1, wherein the execution unit comprises logic that determines a minimum of absolute values of two input values.

5. The processor of claim 1, wherein the execution unit comprises an adder that computes the sum of two input values, and a subtractor that computes the difference of the two input values.

6. The processor of claim 1, wherein the execution unit comprises logic that estimates log(1+e^{-|z|}) where z is the sum of two input values and the difference of the two input values.

7. The processor of claim 1, wherein the execution unit adds the minimum of magnitudes of two input values to a difference of estimated logarithms of exponential functions of a sum and a difference of the two input values.

8. The processor of claim 1, wherein the execution unit operates on signed input values.

9. The processor of claim 1, wherein the execution unit operates on unsigned input values..

10. The processor of claim 1, further comprising a plurality of said execution units; wherein a plurality of LDPC row update values are computed for each row update instruction executed.

11. A system, comprising:
a receiver that comprises:
a processor based low density parity check (“LDPC”) decoder;
wherein the processor executes an LDPC row update instruction that causes the processor to compute, at least a portion of, a check node update value.

12. The system of claim 11, wherein the processor comprises a check node update execution unit that is invoked by execution of the row update instruction.

13. The system of claim 11, wherein the processor adds a minimum of absolute values of two input values and a difference of estimated logarithms of exponential functions of a sum and difference of the two input values while executing the row update instruction.

14. The system of claim 11, wherein the processor comprises a plurality of check node update execution units that are invoked by execution of the row update instruction and computes a plurality of check node update values in parallel.

15. The system of claim 11, wherein the processor takes two previously computed magnitude values as operands for the row update instruction.

16. The system of claim 11, further comprising a transmitter that LDPC encodes data transmitted to the receiver.

17. A low density parity check (“LDPC”) code decoder, comprising:
a processor that comprises an LDPC check node update execution unit that computes, at least a portion of, a check node update value.

18. The LDPC decoder of claim 17, wherein the processor executes an LDPC check node update instruction that causes the check node update execution unit to compute the check node update value.

19. The LDPC decoder of claim 17, wherein the processor comprises a plurality of check node execution units that compute a plurality of check node update values in parallel when the processor executes a row update instruction.

20. The LDPC decoder of claim 17, wherein the check node execution unit sums a minimum magnitude of two input values with a difference of estimated logarithms of exponential functions of a sum and difference of the two input values to generate the check node update value.

21. A method, comprising:
decoding a low density parity check (“LDPC”) code row update instruction in a processor; and
instructing an LDPC row update execution unit in the processor to compute, at least a portion, of an LDPC row update value.

22. The method of claim 21, further comprising decoding an LDPC code row update instruction that directs the execution unit to compute LDPC row update values for a plurality of rows in parallel.

23. The method of claim 21, further comprising computing, in parallel, row update values for a plurality of LDPC rows in the execution unit.

24. The method of claim 21, further comprising computing, in the LDPC row update execution unit, a minimum magnitude of a pair of input values provided to the execution unit.

25. The method of claim 21, further comprising adding, in the LDPC row update execution unit, a minimum magnitude of two input values to a difference of estimated logarithms of exponential functions of a sum and difference of the two input values.
